(19) United States
(12) Patent Application Publication
(10) Pub. No.: US 2024/0176230 A1
(43) Pub. Date: May 30, 2024

(54) METHOD OF CORRECTING EUV OVERLAY AND METHOD OF MANUFACTURING SEMICONDUCTOR DEVICE INCLUDING THE SAME

(71) Applicant: Samsung Electronics Co., Ltd., Suwon-si (KR)

(72) Inventors: Hachul Shin, Suwon-si (KR); Dohyung Kim, Suwon-si (KR); Jooon Park, Suwon-si (KR); Sanghwan Lee, Suwon-si (KR); Seongchul Hong, Suwon-si (KR)

(21) Appl. No.: 18/462,796

(22) Filed: Sep. 7, 2023

(30) Foreign Application Priority Data
Nov. 24, 2022 (KR) 10-2022-0159766

(51) Int. Cl. G03F 1/70

(52) U.S. Cl. CPC G03F 1/70

(57) ABSTRACT

There is provided an extreme ultraviolet (EUV) overlay correcting method capable of effectively correcting an overlay error in an EUV exposure process and a method of manufacturing a semiconductor device including the same. The EUV overlay correcting method includes forming a first photoresist (PR) pattern on a wafer by performing an EUV exposure process using a reticle, inspecting an EUV overlay for the first PR pattern and obtaining a first overlay for a first overlay parameter in which an overlay three-dimensionally increases away from a center to opposing sides of the first PR pattern in a first direction perpendicular to a scan direction, calculating deformation data of the reticle based on the first overlay, applying a voltage to a clamp electrode of a reticle stage to create the reticle into a deformed reticle, and forming a second PR pattern on the wafer by performing an EUV exposure process using the deformed reticle.

### CROSS-REFERENCE TO RELATED APPLICATION

This application is based on and claims priority under 35 U.S.C. § 119 to Korean Patent Application No. 10-2022-0159766, filed on Nov. 24, 2022, in the Korean Intellectual Property Office, the disclosure of which is incorporated by reference herein in its entirety.

### BACKGROUND

The inventive concept relates to a method of correcting an overlay, and more particularly, to a method of correcting an overlay in an extreme ultraviolet (EUV) exposure process.

Recently, as the line width of a semiconductor circuit has gradually been miniaturized, a light source having a shorter wavelength is required. For example, EUV light is used as an exposure light source. Due to the absorption characteristics of EUV light, a reflective EUV mask is generally used in the EUV exposure process. In addition, illumination optics for transmitting EUV light to an EUV mask and projection optics for projecting EUV light reflected from the EUV mask onto an exposure target may include a plurality of mirrors. As the difficulty of the exposure process increases, small errors in an EUV mask or mirrors may cause serious errors in pattern formation on a wafer.

### SUMMARY

The inventive concept relates to an extreme ultraviolet (EUV) overlay correcting method capable of effectively correcting an overlay error in an EUV exposure process and a method of manufacturing a semiconductor device including the same.

Furthermore, the technical challenges of the inventive concept are not limited to the technical challenges mentioned above, and other technical challenges not mentioned will be clearly understood by those skilled in the art from the description below.

According to aspects of the inventive concept, there is provided an extreme ultraviolet (EUV) overlay correcting method including forming a first photoresist (PR) pattern on a wafer by performing an EUV exposure process using a reticle, inspecting an EUV overlay for the first PR pattern and obtaining a first overlay for a first overlay parameter in which an overlay three-dimensionally increases away from a center to opposing sides of the first PR pattern in a first direction perpendicular to a scan direction of the EUV exposure process, calculating deformation data of the reticle based on the first overlay, applying a voltage, based on the deformation data, to a clamp electrode of a reticle stage on which the reticle is settled to create the reticle into a deformed reticle, and forming a second PR pattern on the wafer by performing an EUV exposure process using the deformed reticle.

According to aspects of the inventive concept, there is provided an EUV overlay correcting method including applying a first photoresist (PR) on a wafer, performing EUV exposure on the first PR using a reticle, developing the first PR to form a PR pattern, inspecting an EUV overlay for the PR pattern and obtaining a first overlay for a first overlay parameter in which an overlay three-dimensionally increases away from a center to opposing sides of the PR pattern in a first direction perpendicular to a scan direction of an EUV exposure process, calculating deformation data of the reticle based on the first overlay, applying a voltage, based on the deformation data, to a clamp electrode of a reticle stage on which the reticle is settled to create the reticle into a deformed reticle, applying a second PR on the wafer, and performing EUV exposure on the second PR using the deformed reticle. Performing EUV exposure on the second PR includes applying a tilt to the deformed reticle in a rotational direction about the first direction to perform the EUV exposure process using the deformed reticle.

According to aspects of the inventive concept, there is provided a semiconductor device manufacturing method including performing an extreme ultraviolet (EUV) exposure process using a reticle to form a first photoresist (PR) pattern on a wafer, inspecting an EUV overlay for the first PR pattern and obtaining a first overlay for a first overlay parameter in which an overlay three-dimensionally increases away from a center to opposing sides of the first PR pattern in a first direction perpendicular to a scan direction of the EUV exposure process, determining whether the first overlay is in an allowable range, etching the wafer using the first PR pattern, when it is determined that the first overlay is in the allowable range, performing a subsequent semiconductor process on the wafer, when it is determined that the first overlay is in the allowable range, calculating deformation data of the reticle based on the first overlay, when it is determined that the first overlay is out of the allowable range, applying a voltage, based on the deformation data, to a clamp electrode of a reticle stage on which the reticle is settled to create the reticle into a deformed reticle, and performing an EUV exposure process using the deformed reticle to form a second PR pattern on the wafer.

### BRIEF DESCRIPTION OF THE DRAWINGS

Embodiments will be more clearly understood from the following detailed description taken in conjunction with the accompanying drawings in which:

FIG. 1 is a flowchart schematically illustrating processes of a method of correcting an extreme ultraviolet (EUV) overlay according to some embodiments;

FIG. 2 illustrates a graph for an EUV overlay and an EUV overlay map;

FIG. 3 is a conceptual diagram illustrating image movement in a scan direction in accordance with a change in height of a reticle in non-telecentric optics used in an EUV exposure process;

FIGS. 4A and 4B are conceptual diagrams illustrating a change in height of curved slit-shaped EUV light and a corresponding change in overlay when a tilt is applied to a reticle in an EUV exposure process;

FIGS. 5A and 5B are a plan view of a general clamp electrode and a cross-sectional view of a reticle stage, respectively;

FIGS. 6A and 6B are a plan view of a clamp electrode and a cross-sectional view of a reticle stage, respectively, which are used in operation of creating a deformed reticle in the EUV overlay correcting method of FIG. 1;

FIGS. 7A to 7C are conceptual diagrams illustrating a principle of correcting an EUV overlay using the clamp electrode of FIG. 6A;

FIGS. 8A to 8F are conceptual diagrams illustrating a process of correcting an overlay for K13 in relation to the overlay correcting method of FIG. 1; and

FIG. 9 is a flowchart schematically illustrating processes of a method of manufacturing a semiconductor device including an EUV overlay correcting method according to some embodiments.

### DETAILED DESCRIPTION

Hereinafter, embodiments of the inventive concept will be described in detail with reference to the accompanying drawings. Like numeral references refer to like elements, and their repetitive descriptions are omitted.

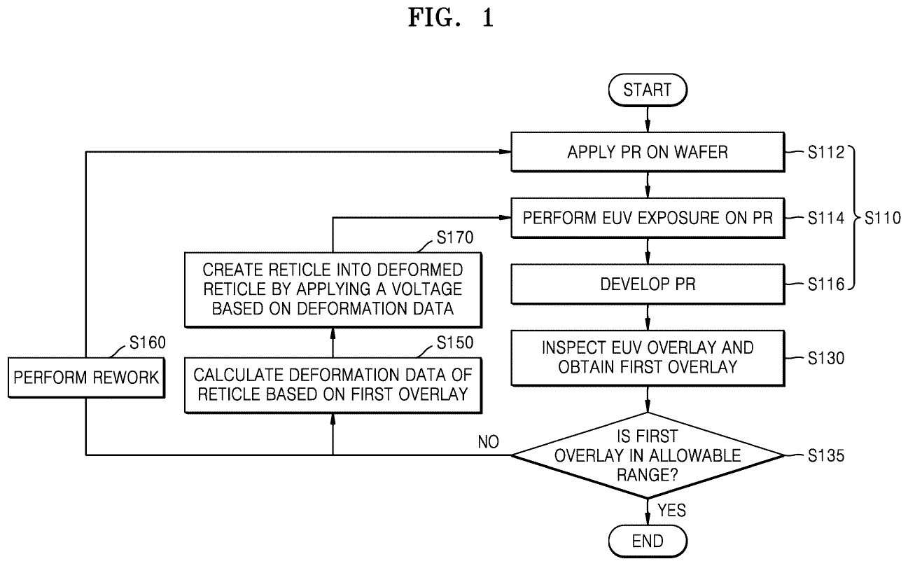

FIG. 1 is a flowchart schematically illustrating processes of a method of correcting an extreme ultraviolet (EUV) overlay according to some embodiments.

Referring to FIG. 1, in the method of correcting an EUV overlay according to some embodiments, first, a photoresist (PR) pattern is formed on a wafer, in operation S110. As used herein, the PR pattern may also be referred to as a first PR pattern. As noted from FIG. 1, operation S110 of forming the PR pattern may include operation S112 of applying PR on the wafer, operation S114 of performing EUV exposure on PR, and operation S116 of developing PR. As used herein, the PR may also be referred to as a first PR.

In operation S112 of applying PR on the wafer, PR may be for EUV exposure. In addition, PR may be applied on the wafer by a spin coating process.

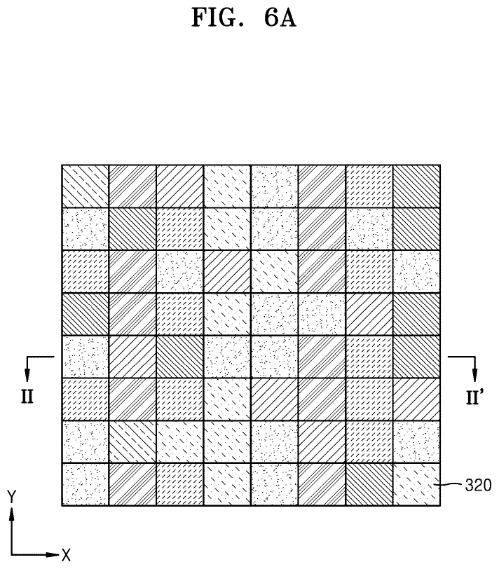

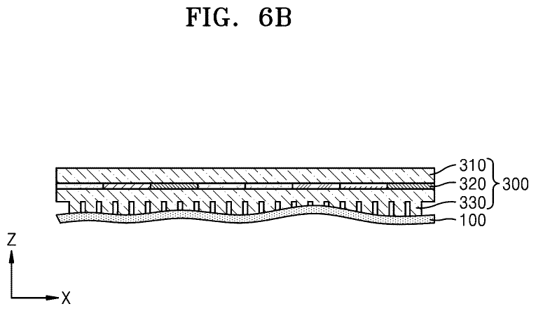

In operation S114 of performing EUV exposure on PR, EUV exposure may be performed by using an EUV exposure apparatus. Briefly, the EUV exposure apparatus may include an EUV light source, a first optical system, a reticle (refer to 100 of FIG. 6B), a reticle stage (refer to 300 of FIG. 6B), a second optical system, and a wafer stage.

The EUV light source may generate and output high energy density EUV light in a wavelength range of about 5 nm to about 50 nm. For example, the EUV light source may generate and output high energy density EUV light with a wavelength of about 13.5 nm. The EUV light source may be a plasma-based light source or a synchrotron radiation light source. On the other hand, the plasma-based light source may include a condensing mirror, such as an elliptical mirror and/or a spherical mirror for concentrating EUV light, in order to increase the energy density of illumination light incident on the first optical system.

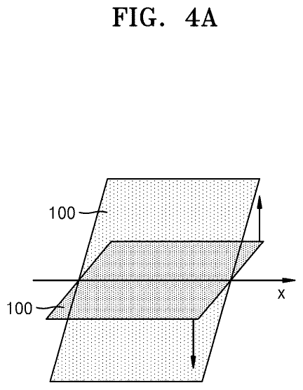

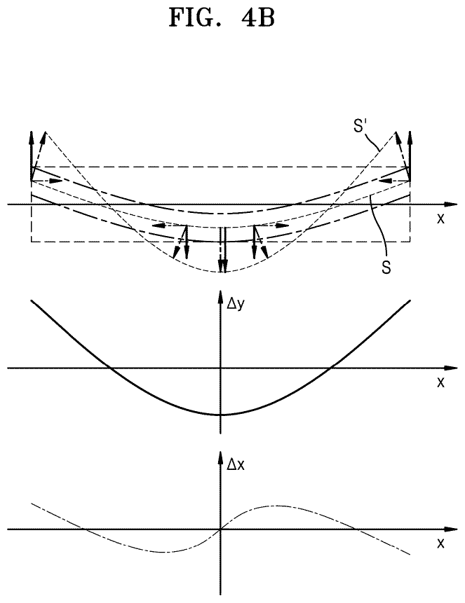

The first optical system may transmit EUV light from the EUV light source to the reticle 100 (see FIG. 6B) through reflection of mirrors. Here, the reticle 100 may mean an EUV mask. Accordingly, the first optical system may include a plurality of mirrors. For example, the first optical system may include two or three mirrors. However, the number of mirrors in the first optical system is not limited to two or three. On the other hand, the first optical system may make EUV light curved slit-shaped and incident on the reticle 100. Here, the curved slit shape of EUV light may mean a parabolic two-dimensional curve on an x-y plane. The curved slit shape of EUV light and the effect thereof are described in more detail with reference to FIGS. 4A and 4B.

The reticle 100 may be a reflective mask having a reflective region and a non-reflective and/or intermediate reflective region. The reticle 100 may include a substrate including a low thermal expansion coefficient material (LTEM), such as quartz, and a reflective multilayer on the substrate and an absorbing layer pattern on the reflective multilayer. The reflective multilayer may reflect EUV light with a structure in which, for example, a molybdenum (Mo) layer and a silicon (Si) layer are alternately stacked in several tens of layers or more. On the other hand, the absorbing layer pattern may include, for example, tantalum nitride (TaN), TaNO, TaBO, nickel (Ni), gold (Au), silver (Ag), carbon (C), tellurium (Te), platinum (Pt), palladium (Pd), or chrome (Cr). However, materials of the reflective multilayer and the absorbing layer pattern are not limited to the materials described above.

The reticle 100 reflects EUV light incident through the first optical system to be incident on the second optical system. More specifically, the reticle 100 reflects EUV light from the first optical system, structures EUV light in accordance with a pattern shape including the reflective multilayer and the absorbing layer pattern, and makes the reflected EUV light be incident on the second optical system. The structured EUV light may be incident on the second optical system, may be transmitted through the second optical system, and may be projected onto an EUV exposure target, for example, the wafer, to form an image corresponding to the pattern shape.

The reticle 100 may be arranged on the reticle stage 300 (see FIG. 6B). For example, the reticle 100 may be settled on the reticle stage 300. The reticle stage 300 may move in X and Y directions on the X-Y plane and may move in a Z direction perpendicular to the X-Y plane. In addition, the reticle stage 300 may rotate based on any one of the X axis, the Y axis, or the Z axis. By such movement or rotation of the reticle stage 300, the reticle 100 may move in the X direction, the Y direction, or the Z direction, or may rotate about the X axis, the Y axis, or the Z axis.

The second optical system may transmit EUV light reflected from the reticle 100 to the wafer as the EUV exposure target through reflection of mirrors. Accordingly, the second optical system may include a plurality of mirrors. For example, the second optical system may include four to eight mirrors. However, the number of mirrors in the second optical system is not limited to four to eight.

The wafer as the EUV exposure target may be arranged on the wafer stage. The wafer stage may move in the X and Y directions on the X-Y plane, and may move in the Z direction perpendicular to the X-Y plane. In addition, the wafer stage may rotate about any one of the X axis, the Y axis, or the Z axis. By the movement or rotation of the wafer stage, the wafer may move in the X direction, the Y direction, or the Z direction, or may rotate about the X axis, the Y axis, or the Z axis.

In operation S116 of developing PR, PR of a portion exposed (or not exposed) by EUV light is removed by using a developer. The developer may be, for example, a non-polar organic solvent, and may selectively remove a soluble region of PR for EUV exposure. On the other hand, operation S116 of developing PR may include a process of preliminarily drying the wafer by removing the developer on the wafer, a process of completely drying the wafer through a baking process, and a process of cooling the wafer. Here, the developer may be removed by using, for example, a supercritical fluid. The PR pattern may be formed on the wafer by developing PR as described above.

After the PR pattern is formed, the EUV overlay is inspected and a first overlay is obtained in operation S130. The EUV overlay may be inspected either by an image based overlay (IBO) method or a diffraction based overlay (DBO) method by using an optical microscope, or by using an electron microscope, such as scanning electron microscopy (SEM) or transmission electron microscopy (TEM). Here, the EUV overlay may occur in EUV exposure. In addition, an overlay means a difference in overlap between a lower layer and a current layer that is an upper layer, and is also referred to as an overlay error. Hereinafter, it is collectively referred to as ‘overlay’. In general, during an exposure process of the upper layer, a shot is taken to match the lower layer as much as possible based on an overlay mark of the lower layer, thereby minimizing the overlay.

When the overlay is large, that is, when a relative positional difference between the lower layer and the current layer is large, the performance of a semiconductor device may be adversely affected. Accordingly, in the exposure process, overlay correction may be performed. Overlay correction may be performed through correction of overlay parameters.

The parameters of the overlay may mean parameters related to the overlay. For example, when an overlay in the X direction is dx and an overlay in the Y direction is dy, there are overlay parameters K1 to K6 that are first order parameters represented as dx=k1, dy=k2, dx=k3*x, dy=k4*y, dx=k5*y, and dy=k6*x. Then, there are overlay parameters K7 to K12 that are second order parameters represented as dx=k7*x², dy=k8*y², dx=k9*x*y, dy=k10*y*x, dx=k11*y², and dy=k12*x². In addition, there are overlay parameters K13 to K20 that are third order parameters represented as, dx=k13*x³, dy=k14*y³, dx=k15*x²*y, dy=k16*y²*x, dx=k17*x*y², dy=k18*y*x², dx=k19*y³, and dy=k20*x³.

In the EUV overlay correcting method according to some embodiments, the first overlay may mean, for example, an overlay for the overlay parameter K13 (hereinafter, simply referred to as ‘K13’). K13 may mean a parameter in which an overlay three-dimensionally increases away from the center to both sides (e.g., opposing sides) in the X direction perpendicular to the Y direction when a scan direction of the EUV exposure process is the Y direction. For reference, when the overlay relates to the wafer stage, it may be prefixed with a W in front of the K, and when the overlay relates to the reticle stage, it may be prefixed with an R in front of the K. Accordingly, in the EUV overlay correcting method according to some embodiments, a first overlay parameter may correspond to RK13, strictly speaking. However, for convenience sake, hereinafter, RK13 is represented as K13 and RK12 is represented as K12.

For reference, in a deep ultraviolet (DUV) exposure apparatus, for example, an ArFi exposure apparatus, all overlay parameters may be corrected by a physical operation. On the other hand, in the EUV exposure apparatus, most overlay parameters may be corrected by a physical operation like in the ArFi exposure apparatus. However, in the EUV exposure apparatus, K13 is classified as almost impossible to correct through a physical operation due to a difference in hardware between the EUV exposure apparatus and the ArFi exposure apparatus.

More specifically, in the EUV exposure process, an overlay may be caused by several factors. For example, high order distortion may occur due to inaccuracies of mirrors in the optical system, clamping errors of the reticle stage, reticle contamination, and reticle writing errors. This is exposed by adjusting movements of the reticle, the wafer, and the mirrors during exposure in the EUV exposure apparatus to compensate for up to the five-order term. However, a non-correctable error (NCE) of a higher-order overlay still remains. Here, the NCE may mean a final overlay that may not be corrected by the EUV exposure apparatus. In order to solve this problem, reticle writing correction (RWC) technology of pre-correcting the NCE when a pattern is written on a reticle, and technology of matching an overlay between DUV and EUV by reflecting K13 in advance by a DUV exposure apparatus capable of correcting K13 when a previous layer is formed by a DUV exposure process are used. However, when the higher-order overlay including K13 is not fixed and drifts, the correcting method described above has limitations. Recently, as an overlay margin has been gradually decreasing, a control knob capable of correcting K13 or a higher-order overlay to some extent in the EUV exposure apparatus is required.

Then, it is determined whether the first overlay is in an allowable range, in operation S135. When it is determined that the first overlay is in the allowable range (YES), the EUV overlay correcting method is terminated. Here, termination of the EUV overlay correcting method may mean terminating correction for the first overlay. Therefore, an overlay related to another overlay parameter may still be corrected by a conventional correcting method.

When the first overlay is out of the allowable range (NO), deformation data of the reticle 100 is calculated based on the first overlay, in operation S150. Here, the deformation data of the reticle 100 may be calculated from a second overlay for a second overlay parameter. In addition, the second overlay may be calculated from a correlation with the first overlay. Here, in the second overlay parameter, an overlay two-dimensionally increases in a scan direction, that is, in the Y direction away from the center in the X direction. For example, the second overlay parameter may be K12.

In general, a correlation between the second overlay parameter and the first overlay parameter means a ratio between a correction value of the second overlay parameter and a correction value of the first overlay parameter, and in the overlay correcting method according to some embodiments, a correlation between K12 and K13 may be represented as 1:K and K may be about −0.25. Specifically, when the second overlay parameter is K12 and the first overlay parameter is K13, a correlation of K12:K13=4:−1 may be obtained. Based on the correlation, when the overlay for the first overlay parameter, that is, K13, is corrected by −1, the overlay for the second overlay parameter, that is, K12, may be corrected by 4. Conversely, when the overlay for K12 is corrected by 4, the overlay for K13 may be corrected by −1. As described above, in the EUV exposure process, K13 may not be corrected. Accordingly, in the EUV overlay correcting method according to some embodiments, a method of correcting K13 by correcting K12 based on the correlation may be used. The correlation between K12 and K13 and the resulting overlay correction are described in more detail in the description of FIGS. 4A and 4B.

On the other hand, the overlay for K12 used for calculating the deformation data may correspond to an overlay calculated based on the correlation with the overlay for K13, not an actual overlay occurring in the EUV exposure process. In other words, the overlay for K12, which is required for correcting the overlay for the first overlay parameter obtained by overlay inspection, that is, K13, may be calculated as the deformation data.

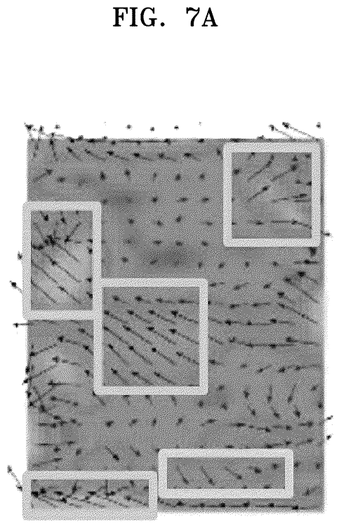

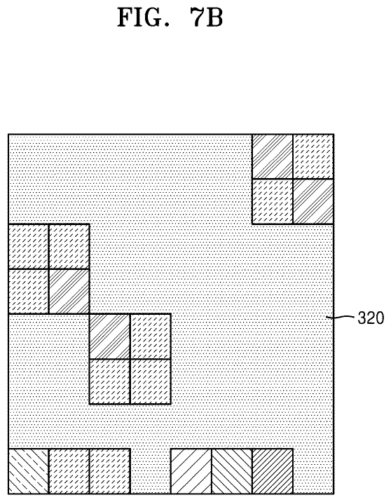

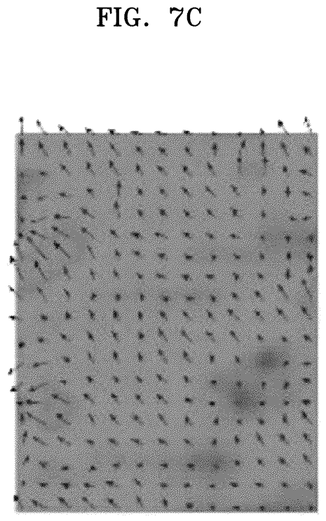

After calculating the deformation data, the reticle 100 is created into a deformed reticle (refer to 100 in FIG. 6B) by applying a voltage based on the deformation data, in operation S170. In the EUV overlay correcting method according to some embodiments, the deformed reticle 100 may be implemented by applying voltages required for split electrodes of a clamp electrode (refer to 320 of FIG. 6B) of the reticle stage 300 based on the deformation data. For reference, the split electrodes of the clamp electrode 320 are arranged in a two-dimensional array structure and a voltage may be applied to each of the split electrodes of the clamp electrode 320. Structures of the split electrodes of the clamp electrode 320, a process of creating the deformed reticle 100 by using the clamp electrode 320, and a resulting overlay correcting process are described in more detail with reference to FIGS. 6A to 7C.

On the other hand, when the first overlay is out of the allowable range (NO), rework is performed in operation S160 in parallel with operation S150 of calculating the deformation data and operation S170 of creating the deformed reticle 100. The rework may mean a process of removing the PR pattern (e.g., the first PR pattern) on the wafer.

After operation S160 of performing the rework, operation S112 of applying PR of operation S110 of forming the PR pattern is performed. As used herein, the PR applied after operation S160 of performing the rework may also be referred to as a second PR or a new PR, and the PR pattern formed after operation S160 of performing the rework may also be referred to as a second PR pattern. For example, operation S160 of performing the rework may include removing the first PR pattern on the wafer. For example, operation S112 of applying PR after operation S160 may include applying a new PR on the wafer. In addition, after operation S170 of creating the deformed reticle 100, operation S114 of performing EUV exposure of operation S110 of forming the PR pattern (e.g., the second PR pattern) is performed. Subsequently, operation S116 of performing development and operation S130 of obtaining the first overlay are performed. Such a process may be repeated until the first overlay is in the allowable range.

On the other hand, after operation S114 of performing first EUV exposure, in operation S114 of performing subsequent EUV exposure, the deformed reticle 100 may be used for the EUV exposure process. In addition, in order to correct the overlay for K12, which newly occurs due to the deformed reticle 100 in the EUV exposure process, a tilt may be applied to the deformed reticle 100 in a rotational direction about the X axis. In this way, by applying the tilt to the deformed reticle 100, the overlay for K12 may be corrected, and based on the correlation between K12 and K13, the overlay for K13 may be corrected.

In the EUV overlay correcting method according to some embodiments, by correcting the overlay for the second overlay parameter, that is, K12, the overlay for the first overlay parameter correlated with K12, that is, K13 may be corrected. More specifically, the overlay for K13 is obtained through overlay inspection, and the deformation data of the reticle 100 is calculated by using the correlation between K12 and K13. The deformation data of the reticle 100 may be calculated as the overlay for K12, which is required for correcting the overlay for K13. Then, in order to induce the overlay for K12, the reticle 100 is created into the deformed reticle 100 through voltage application based on the deformation data. The deformed reticle 100 may be created by independently applying a voltage to the split electrodes of the clamp electrode 320 in the reticle stage 300 based on the deformed data. Then, in the EUV exposure, by applying the tilt to the deformed reticle 100 in the rotational direction about the X axis, the overlay for K12 and the overlay for K13 correlated with K12 may be corrected. As a result, by the EUV overlay correcting method according to some embodiments, the entire EUV overlay including K13 may be effectively corrected.

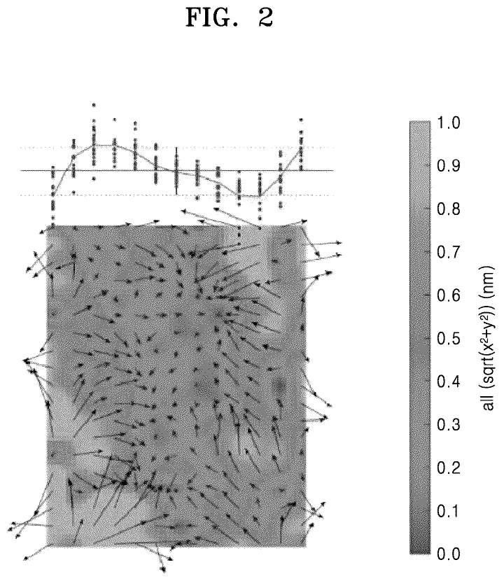

FIG. 2 illustrates an EUV overlay graph and an EUV overlay map.

Referring to FIG. 2, the EUV overlay map (at the bottom below the EUV overlay graph) represents overlays as arrows and black and white shading. In the case of overlays marked with arrows, an overlay is illustrated through a direction and a length at each position. On the other hand, in the case of overlays displayed in black and white shading, a degree of an overlay for each region is illustrated through a difference in shading for each region.

On the other hand, the EUV overlay graph illustrates the average overlay in the X direction in the EUV overlay map. Based on the graph shape, it may be noted that the overlay on the graph corresponds to the overlay for K13.

For reference, the overlay of the EUV overlay map of FIG. 2 may correspond to the NCE. In other words, NCE may mean overlays remaining after overlays for correctable overlay parameters are corrected. Therefore, it may be predicted that the overlay on the EUV overlay map and the graph of FIG. 2 corresponds to the overlay for K13. On the other hand, the EUV overlay map of FIG. 2 may include fourth or fifth order overlay.

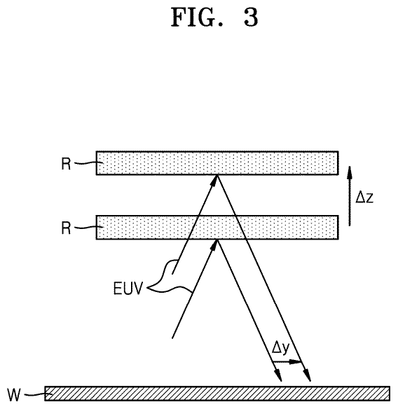

FIG. 3 is a conceptual diagram illustrating an image shift in a scan direction according to a change in height of a reticle in non-telecentric optics used in an EUV exposure process.

Referring to FIG. 3, the EUV exposure apparatus may have non-telecentric optical characteristics. In other words, in an optical system of the EUV exposure apparatus, a size of a phase may vary depending on a distance. Therefore, as illustrated in FIG. 3, when a distance between a reticle R and a wafer W varies, an image moves on the wafer W. In general, EUV light may be incident on the reticle R with a tilt of 6°. Therefore, when the reticle R moves in the vertical direction, that is, a third direction (the Z direction), a movement distance Δy of the image on the wafer W according to a movement distance Δz in the vertical direction may be calculated as illustrated in EQUATION (1).

Δy=¼*tan 6°*Δz≈Δz/40 EQUATION (1)

In EQUATION (1), ‘¼’ may be a value introduced because a pattern of the reticle is reduced by ¼ And transferred onto the wafer W in the EUV exposure process.

FIGS. 4A and 4B are conceptual diagrams illustrating a change in height of curved slit-shaped EUV light S and a corresponding change in overlay when a tilt is applied to a reticle 100 used in an EUV exposure process.

Referring to FIGS. 4A and 4B, when a tilt (hereinafter, referred to as ‘Rx-tilt’) is applied to the reticle 100 in a direction in which the reticle 100 rotates about the X axis as illustrated in FIG. 4A, the curved slit-shaped EUV light S has a change in height from the center (e.g., from the center of the X axis) to the ends (e.g., to the ends of the X axis) as illustrated in FIG. 4B. In other words, in FIG. 4B, first slit-shaped EUV light S when the Rx-tilt is not applied to the reticle 100 is changed to second slit-shaped EUV light S′ when the Rx-tilt is applied to the reticle 100. The change in height of the slit-shaped EUV light induces the overlays for K12 and K13 due to the non-telecentric optical characteristics of the EUV exposure process. In FIG. 4B, a graph of quadratic Δy in the X direction is an overlay graph for K12, and a graph of cubic Δx in the X direction is an overlay graph for K13. In other words, by applying the Rx-tilt to the reticle 100, the overlay for K12 and the overlay for K13 may occur, and conversely, the overlay for K12 and the overlay for K13 may be corrected by applying the Rx-tilt to the reticle 100. In addition, because there is the above-described correlation between K12 and K13, the overlay for K13 may be corrected by correcting the overlay for K12 in the EUV exposure apparatus.

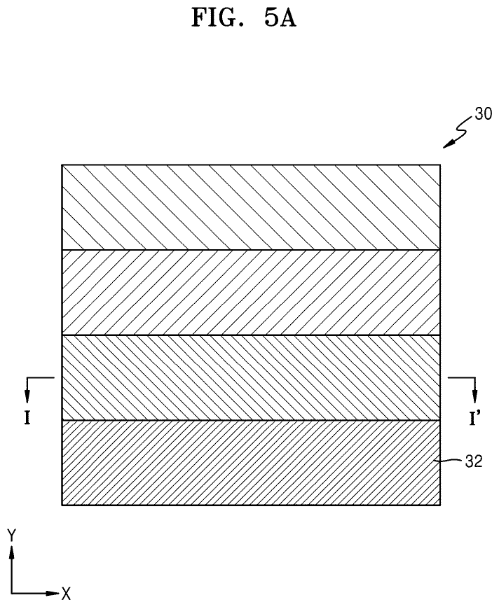

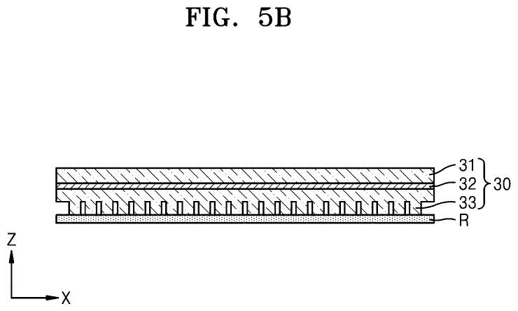

FIGS. 5A and 5B are a plan view of a clamp electrode of a reticle stage 30 and a cross-sectional view of the reticle stage, respectively. In particular, FIG. 5B is a cross-sectional view of the reticle stage taken along the line I-I′ of FIG. 5A. FIGS. 6A and 6B are a plan view of a clamp electrode of a reticle stage 300 used in operation of creating a deformed reticle in the EUV overlay correcting method of FIG. 1 and a cross-sectional view of the reticle stage, respectively. In particular, FIG. 6B is a cross-sectional view of a reticle stage taken along the line II-II′ of FIG. 6A.

Referring to FIGS. 5A and 5B, the reticle stage 30 may include a body 31, a clamp electrode 32, and a plurality of burls 33. In addition, the body 31 may include an LTEM, such as glass or quartz.

The clamp electrode 32 is arranged in the body 31 and may include a conductive material, such as a metal. As illustrated in FIG. 5A, the clamp electrode 32 may include several split electrodes, for example, four split electrodes extending in the X direction and split into one another in the Y direction. Here, the split electrodes may be electrically insulated from one another. Therefore, a voltage may be applied to each of the split electrodes. By applying a voltage to the clamp electrode 32, the reticle R may be fixed onto a bottom surface of the reticle stage 30 by electrostatic attraction. In other words, when the voltage is applied to the clamp electrode 32, the reticle R may be fixed in close contact with the plurality of burls 33 of the reticle stage 30 by electrostatic attraction.

The plurality of burls 33 may be cylinders protruding or extending from a bottom surface of the body 31. The plurality of burls 33 are arranged on the bottom surface of the body 31 and may be coated with a titanium nitride (TiN) layer. In addition, according to some embodiments, the inventive concept is not limited thereto and the plurality of burls 33 may be coated with another material. When the voltage is applied to the clamp electrode 32, the reticle R may contact the plurality of burls 33 and may be fixed in close contact with the reticle stage 30.

In the reticle stage 30, because a size of each of the split electrodes is large, although different voltages are applied to the split electrodes, the reticle R may not be deformed. In other words, tens to hundreds of burls 33 may be arranged corresponding to one split electrode. Therefore, when a voltage is applied to one split electrode, the same electrostatic force is generated throughout the split electrode, and it is difficult to contract all the burls 33 corresponding to the split electrode and to deform the corresponding reticle R. As a result, in the reticle stage 30, the reticle R may not be deformed by applying a voltage.

Referring to FIGS. 6A and 6B, in the EUV overlay correcting method according to some embodiments, the reticle stage 300 of the EUV exposure apparatus may be different from the reticle stage 30. Specifically, the reticle stage 300 may include a body 310, a clamp electrode 320, and a plurality of burls 330. The body 310 may include an LTEM, such as glass or quartz like the body 31 of the reticle stage 30.

On the other hand, the clamp electrode 320 is arranged in the body 310 and may include a conductive material, such as a metal. In addition, the clamp electrode 320 may include a plurality of split electrodes, for example, N*M (N and M are integers equal to or greater than 2, respectively) split electrodes arranged in a two-dimensional array structure in the X and Y directions as illustrated in FIG. 6A. The split electrodes may be electrically insulated from one another. Therefore, a voltage may be applied to each of the split electrodes. By applying a voltage to the clamp electrode 320, the reticle 100 may be fixed by electrostatic attraction. In other words, when the voltage is applied to the clamp electrode 320, the reticle 100 may be fixed in close contact with the plurality of burls 330 of the reticle stage 300 by electrostatic attraction.

The plurality of burls 330 may be cylinders protruding or extending from a bottom surface of the body 310. The plurality of burls 330 are arranged on the bottom surface of the body 310 and may be coated with a chromium nitride (CrN) layer. When the voltage is applied to the clamp electrode 320, the reticle 100 may contact the plurality of burls 330 and may be fixed in close contact with the reticle stage 300.

In the reticle stage 300 used in the EUV overlay correcting method according to some embodiments, a size of each of the split electrodes is very small so that the reticle 100 may be deformed as illustrated in FIG. 6B. In other words, only several burls 330 may be arranged corresponding to one split electrode. Therefore, when a voltage is applied to one split electrode, electrostatic force is generated only in a corresponding portion of the split electrode, and the burls 330 corresponding thereto may be contracted (e.g., may contract) and a corresponding portion of the reticle 100 may be deformed. As a result, in the reticle stage 300 used in the EUV overlay correcting method according to some embodiments, the reticle 100 may be deformed into a required shape by independently applying voltages to the split electrodes of the clamp electrode 320. Here, the deformation of the reticle 100 may mean a change in height in the Z direction at each portion in the X and Y directions.

FIGS. 7A to 7C are conceptual diagrams illustrating a principle of correcting an EUV overlay by using the clamp electrode of FIG. 6A. In particular, FIG. 7A illustrates an EUV overlay map, FIG. 7B illustrates a form of a voltage applied to the clamp electrode, and FIG. 7C illustrates an EUV overlay map in which an overlay is corrected by applying the voltage of FIG. 7B.

Referring to FIG. 7A, the overlay of the EUV overlay map may correspond to, for example, the NCE. In other words, the EUV overlay map of FIG. 7A illustrates overlays remaining after overlays for all correctable parameters are corrected in a common EUV exposure apparatus. On the other hand, in FIG. 7A, white squares may correspond to portions in which large overlays occur. For example, it may be noted that lengths of arrows in the white squares are greater than lengths of arrows in the other portions, and squares appear brighter than the other portions even in the overlays marked with black and white shading. Therefore, the overlays of the squares may be required to be corrected.

Referring to FIG. 7B, higher voltages are applied to the split electrodes of the clamp electrode 320 corresponding to the squares of FIG. 7A than to the other portions. In addition, as illustrated in FIG. 7B, different voltages may be applied to the split electrodes in each of the squares. In this way, by applying high voltages to the split electrodes of the clamp electrode 320 corresponding to the squares, the reticle 100 arranged on a bottom surface of the reticle stage 300 may be deformed into a required shape.

On the other hand, voltages of the same magnitude may be applied to portions other than the squares. However, according to some embodiments, portions other than the squares may also be divided into large regions, to which different voltages may be applied.

Referring to FIG. 7C, like in FIG. 7B, the EUV exposure process may be performed in a state in which voltages are applied to the split electrodes of the clamp electrode 320 so that the overlays of the squares may be corrected. That is, it may be noted from the EUV overlay map of FIG. 7C that the lengths of the arrows corresponding to the overlays of the squares are reduced. In addition, it may be noted that the squares appear dark similarly to the other portions even in the overlays marked with black and white shading.

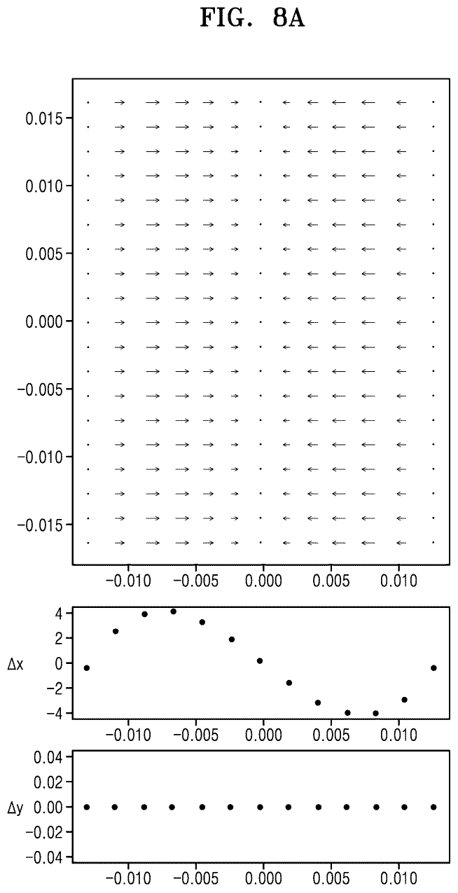

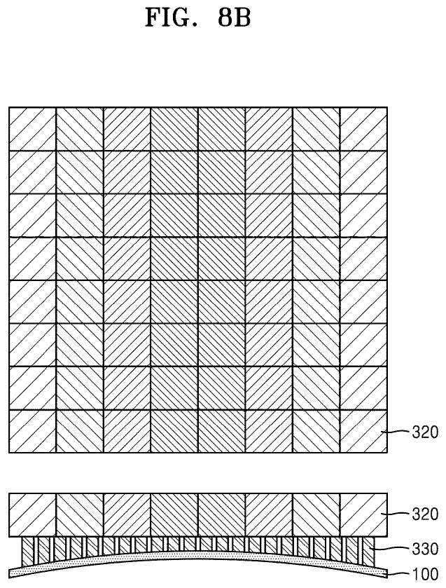

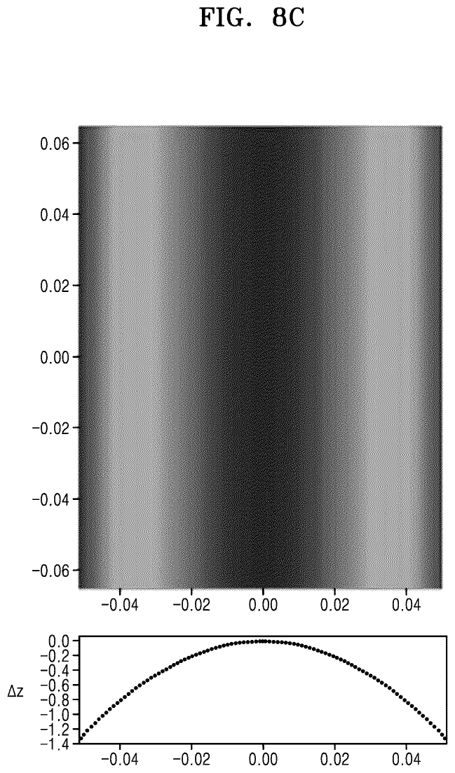

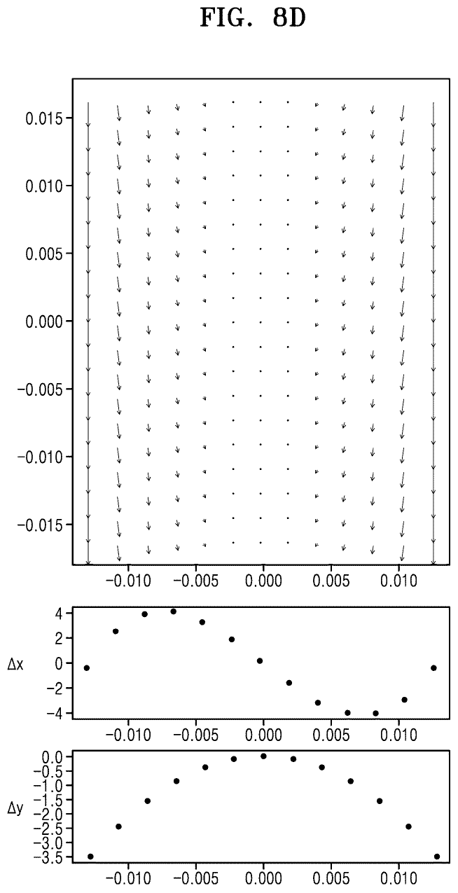

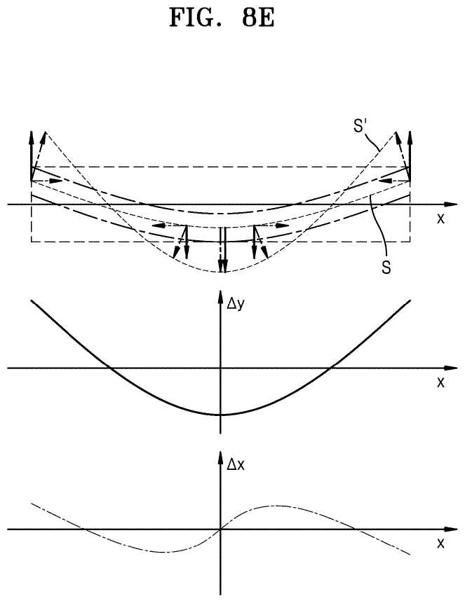

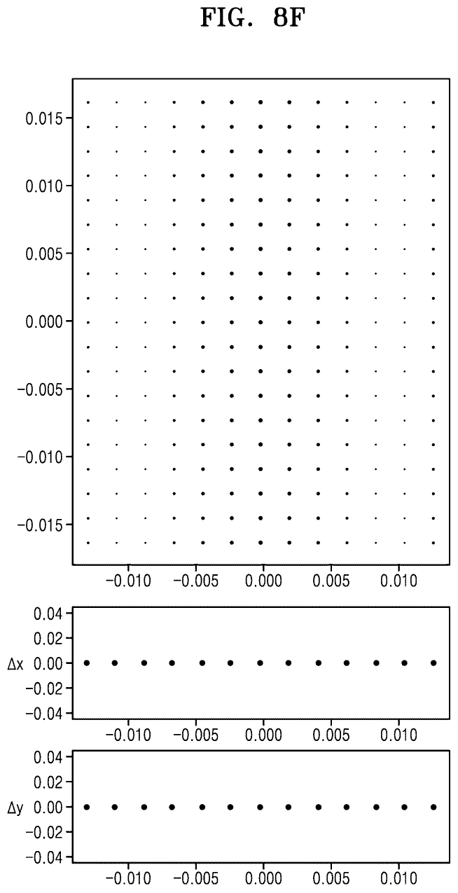

FIGS. 8A to 8F are conceptual diagrams illustrating a process of correcting an overlay for K13 in relation to the overlay correcting method of FIG. 1. Description will be given with reference to FIGS. 6A and 6B together, and description previously given with reference to FIGS. 1 to 7C will be briefly given or will not be given for ease of description. On the other hand, in FIGS. 8A to 8F, a unit of numerical values for positions in the X and Y directions is meters (m), and a unit of numerical values related to an overlay is 10⁻⁷ m. For example, a unit of numerical values of Δx, Δy, and Δz may be 10⁻⁷ m.

Referring to FIG. 8A, the largest square box at the top illustrates the overlays for K12 and K13 on the X-Y plane after performing the EUV exposure process by using the reticle 100 before deformation. As marked with arrows, the overlay for K13 may three-dimensionally increase in the X direction. Here, the X direction may be perpendicular to the Y direction that is a scan direction in the EUV exposure process.

On the other hand, graphs at the bottom of FIG. 8A represent sizes of the overlays in the largest square box at the top in the X direction. Specifically, the upper graph represents the size Δx of the overlay for K13 in the X direction, and the lower graph represents the size Δy of the overlay for K12 in the X direction. For reference, the overlay for K12 in the Y direction may two-dimensionally increase in the X direction.

From the largest square box at the top and the graphs at the bottom, it may be noted that only the overlay for K13 currently exists, and the overlay for K12 does not exist.

Referring to FIG. 8B, the reticle 100 is deformed by applying different voltages to the split electrodes of the clamp electrode 320 of the reticle stage 300. For example, a high voltage may be applied to the center (e.g., the center of the clamp electrode 320) and low voltages may be applied to both edges in the X direction (e.g., both edges of the clamp electrode 320 in the X direction). For example, a high voltage may be applied to one or more split electrodes in the center of the clamp electrode 320 and low voltages may be applied to one or more split electrodes at opposing edges in the X direction of the clamp electrode 320. By applying different voltages to the split electrodes of the clamp electrode 320 as described above, the reticle 100 may be deformed into a quadratic parabola with the high center and the low both edges in the X direction, as illustrated in a cross-sectional view at the bottom of FIG. 8B. For example, the deformed reticle 100 may be formed in a shape of a parabola having a center as an upper portion and opposing edges in the X direction as respective lower portions. For example, a vertical height (e.g., in the Z direction) of the deformed reticle 100 from the wafer may vary in the X direction. For reference, the cross-sectional view at the bottom of FIG. 8B conceptually illustrates only the clamp electrode 320 and the burls 330 without illustrating the body 310.

Referring to FIG. 8C, a square at the top illustrates a height map for the reticle 100 in black and white shading, and a graph at the bottom illustrates a difference in height Δz of the reticle 100 in the X direction. It may be noted from the height map at the top and the graph at the bottom that the reticle 100 is in the form of a quadratic parabola with the high center and the low both edges in the X direction (e.g., low opposing edges in the X direction).

Referring to FIG. 8D, the largest square box at the top illustrates the overlays for K12 and K13 on the X-Y plane after performing the EUV exposure process by using the deformed reticle 100 described with reference to FIG. 8B or 8C. In addition, graphs at the bottom represent sizes of the overlays in the largest square box at the top in the X direction. As noted from FIG. 8D, after the EUV exposure process is performed by using the deformed reticle 100, in addition to the overlay for K13, the overlay for K12 may additionally occur. That is, by deforming the reticle 100 into a quadratic parabola, the overlay for K12 may be induced. On the other hand, from the graph of Δx in FIG. 8A and the graph of Δx in FIG. 8D, it may be noted that the overlay for K13 is maintained regardless of the deformation of the reticle 100.

Referring to FIG. 8E, after the reticle 100 is deformed by applying a voltage, the Rx-tilt is applied to the deformed reticle 100. Accordingly, as illustrated in FIG. 8E, the curved slit-shaped EUV light S has a change in height from the center to the ends as illustrated in FIG. 8E. In other words, in FIG. 8E, first slit-shaped EUV light S when the Rx-tilt is not applied to the deformed reticle 100 is changed to second slit-shaped EUV light S′ when the Rx-tilt is applied to the deformed reticle 100. The change in height of the slit-shaped EUV light induces, that is, reduces or increases the overlays for K12 and K13 due to the non-telecentric optical characteristics of the EUV exposure process. In other words, the overlays for K12 and K13 may be increased or reduced by applying the Rx-tilt to the deformed reticle 100. In addition, based on the correlation between K12 and K13, by reducing the overlay for K12 in the EUV exposure apparatus, the overlay for K13 may be reduced.

Accordingly, the overlay for K12 induced through the deformation of the reticle 100 may have a size at a level at which the overlay for K13 may be removed by removing the overlay for K12 based on the correlation between K12 and K13. In addition, the overlay for K12 may be calculated in accordance with the correlation between K12 and K13 based on the overlay for K13 obtained through overlay inspection. In addition, based on the calculated K12, a degree of deformation of the reticle 100 and voltages required for the split electrodes for such deformation may be calculated.

Referring to FIG. 8F, the largest square box at the top illustrates the overlays for K12 and K13 on the X-Y plane after performing the EUV exposure process by using the deformed reticle 100 with the Rx-tilt applied. In addition, graphs at the bottom represent sizes of the overlays in the largest square box at the top in the X direction. Here, the Rx-tilt may be at a level at which the overlay for K12 may be removed. It may be noted from FIG. 8F that the overlays for K12 and K13 are greatly reduced to almost zero after performing the EUV exposure process by using the deformed reticle 100 with the Rx-tilt applied.

As a result, in the EUV overlay correcting method according to some embodiments, the overlay for K13 may be first obtained and the overlay for K12 may be calculated based on the correlation between K12 and K13. In addition, in order to induce the overlay for K12, the degree of deformation of the reticle 100 and the voltages required for the split electrodes for such deformation may be calculated. Then, the corresponding voltages are applied to the split electrodes to deform the reticle 100. Subsequently, by applying the Rx-tilt to the deformed reticle 100 and performing the EUV exposure process, the induced overlay for K12 may be corrected, and the overlay for K13 may be corrected by the correlation between K12 and K13.

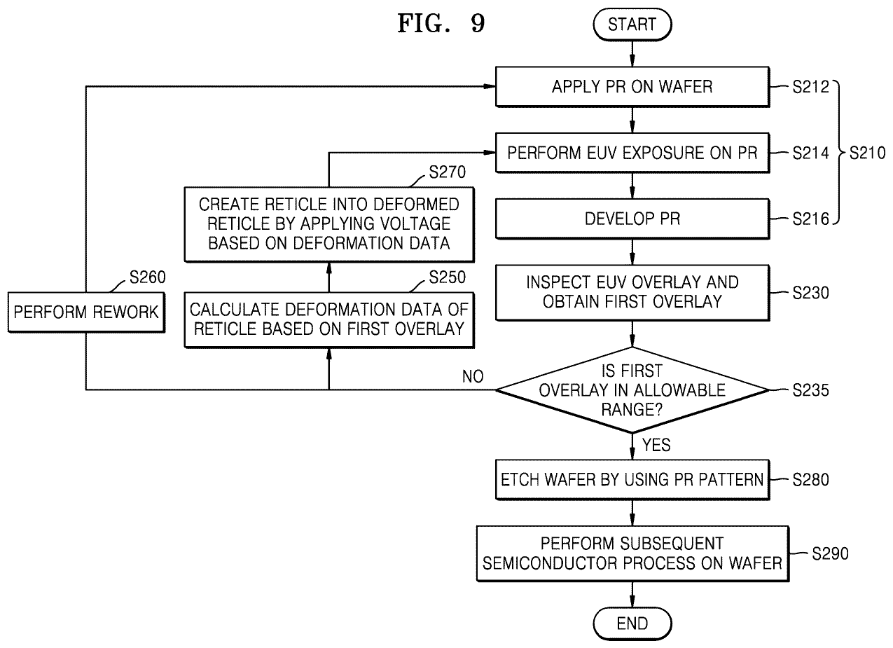

FIG. 9 is a flowchart schematically illustrating processes of a method of manufacturing a semiconductor device including an EUV overlay correcting method according to some embodiments. Description previously given with reference to FIGS. 1 to 8F will be briefly given or will not be given for ease of description.

Referring to FIG. 9, a semiconductor device manufacturing method including the EUV overlay correcting method according to some embodiments (hereinafter, simply referred to as a ‘semiconductor device manufacturing method’) includes operation S210 of forming a PR pattern, operation S230 of obtaining a first overlay, operation S235 of determining whether the first overlay is in an allowable range, operation S250 of calculating deformation data, operation S260 of performing rework, and operation S270 of creating a deformed reticle. Operation S210, operation S230, operation S235, operation S250, operation S260, and operation S270 of FIG. 9 are the same as described in operation S110, operation S130, operation S135, operation S150, operation S160, and operation S170, respectively, in the EUV overlay correcting method of FIG. 1 and thus further descriptions thereof will be omitted for ease of description.

On the other hand, unlike in the EUV overlay correcting method of FIG. 1, in the semiconductor device manufacturing method according to some embodiments, when the first overlay is in the allowable range (YES), a wafer is etched by using the PR pattern, in operation S280. That is, by using the PR pattern as a mask, a layer under the PR pattern is etched by an etching process. Here, the etching of the wafer may be etching of a substrate, such as a silicon substrate, or etching of another material layer on the substrate. After etching the wafer, the PR pattern may be removed by an ashing/strip process.

Then, a subsequent semiconductor process is performed on the wafer, in operation S290. The subsequent semiconductor process may include various processes. For example, the subsequent semiconductor process may include a deposition process, an etching process, an ion process, and a cleaning process. On the other hand, when the etching process includes an EUV exposure process, the overlays, in particular, the overlay for K13 may be minimized by previously performing the operation S210 of forming the PR pattern to the operation S270 of creating the deformed reticle.

On the other hand, the subsequent semiconductor process may include a singulation process of individualizing the wafer into semiconductor chips, a test process of testing the semiconductor chips, and a packaging process of packaging the semiconductor chips. A semiconductor device may be completed by the subsequent semiconductor process for the wafer.

As used herein, the terms “comprises”, “comprising”, “includes”, “including”, “has”, “having” and any other variations thereof specify the presence of the stated features, integers, steps, operations, elements, and/or components, but do not preclude the presence or addition of one or more other features, integers, steps, operations, elements, components, and/or groups thereof.

While the inventive concept has been particularly shown and described with reference to embodiments thereof, it will be understood that various changes in form and details may be made therein without departing from the scope of the following claims.

What is claimed is:

1. A method of correcting an extreme ultraviolet (EUV) overlay, the method comprising:
forming a first photoresist (PR) pattern on a wafer by performing an EUV exposure process using a reticle;
inspecting an EUV overlay for the first PR pattern and obtaining a first overlay for a first overlay parameter in which an overlay three-dimensionally increases away from a center to opposing sides of the first PR pattern in a first direction perpendicular to a scan direction of the EUV exposure process;
calculating deformation data of the reticle based on the first overlay;
applying a voltage, based on the deformation data, to a clamp electrode of a reticle stage on which the reticle is settled to create the reticle into a deformed reticle; and
forming a second PR pattern on the wafer by performing an EUV exposure process using the deformed reticle.

2. The method of claim 1, wherein the clamp electrode comprises a plurality of split electrodes arranged in a two-dimensional array structure, and
wherein the deformed reticle is created by applying voltages to the split electrodes, respectively.

3. The method of claim 1, wherein the reticle stage comprises a plurality of burls protruding on a surface contacting the reticle, and
wherein the plurality of burls contract and the reticle is deformed as the reticle is in close contact with the reticle stage by applying the voltage.

4. The method of claim 1, wherein the deformed reticle is formed in a shape of a parabola having a center as an upper portion and opposing edges in the first direction as respective lower portions.

5. The method of claim 1, wherein performing the EUV exposure process using the deformed reticle comprises applying a tilt to the deformed reticle in a rotational direction about the first direction.

6. The method of claim 5, wherein calculating the deformation data comprises calculating the deformation data based on a correlation between the first overlay parameter and a second overlay parameter in which an overlay two-dimensionally increases in the scan direction away from the center in the first direction.

7. The method of claim 6, wherein a second overlay for the second overlay parameter is induced by the deformed reticle,
wherein the tilt is applied to the deformed reticle in the rotational direction about the first direction to correct the second overlay, and
wherein the first overlay is corrected based on the correlation between the first overlay parameter and the second overlay parameter.

8. The method of claim 1, wherein forming the first PR pattern comprises:
applying PR on the wafer;
performing EUV exposure on the PR; and
developing the PR.

9. The method of claim 1, wherein, before performing the EUV exposure process using the deformed reticle, rework of removing the first PR pattern on the wafer is performed and a new PR is applied on the wafer.

10. The method of claim 1, wherein a vertical height of the deformed reticle from the wafer varies in the first direction,
wherein a difference in height of the deformed reticle in the first direction induces a second overlay for a second overlay parameter in which an overlay two-dimensionally increases in the scan direction,
wherein a tilt is applied to the deformed reticle in a rotational direction about the first direction to remove the second overlay, and
wherein the first overlay is removed based on a correlation between the first overlay parameter and the second overlay parameter.

11. A method of correcting an extreme ultraviolet (EUV) overlay, the method comprising:
applying a first photoresist (PR) on a wafer;
performing EUV exposure on the first PR using a reticle;
developing the first PR to form a PR pattern;
inspecting an EUV overlay for the PR pattern and obtaining a first overlay for a first overlay parameter in which an overlay three-dimensionally increases away from a center to opposing sides of the PR pattern in a first direction perpendicular to a scan direction of an EUV exposure process;
calculating deformation data of the reticle based on the first overlay;
applying a voltage, based on the deformation data, to a clamp electrode of a reticle stage on which the reticle is settled to create the reticle into a deformed reticle;
applying a second PR on the wafer; and
performing EUV exposure on the second PR using the deformed reticle,
wherein performing EUV exposure on the second PR comprises applying a tilt to the deformed reticle in a rotational direction about the first direction to perform the EUV exposure process using the deformed reticle.

12. The method of claim 11, wherein the clamp electrode comprises a plurality of split electrodes arranged in a two-dimensional array structure, and
wherein the deformed reticle is created by applying voltages to the split electrodes, respectively.

13. The method of claim 11, wherein the deformed reticle is formed in a shape of a parabola having a center as an upper portion and opposing edges in the first direction as respective lower portions.

14. The method of claim 11, wherein calculating the deformation data comprises calculating a second overlay for a second overlay parameter, in which an overlay two-dimensionally increases in the scan direction away from the center in the first direction, based on a correlation between the first overlay parameter and the second overlay parameter,
wherein the second overlay is induced by the deformed reticle,
wherein the tilt is applied to the deformed reticle in the rotational direction about the first direction to correct the second overlay, and
wherein the first overlay is corrected based on the correlation between the first overlay parameter and the second overlay parameter.

15. The method of claim 11, wherein, before performing EUV exposure using the deformed reticle, the PR pattern on the wafer is removed and the second PR is applied on the wafer.

16. A method of manufacturing a semiconductor device, the method comprising:
performing an extreme ultraviolet (EUV) exposure process using a reticle to form a first photoresist (PR) pattern on a wafer;
inspecting an EUV overlay for the first PR pattern and obtaining a first overlay for a first overlay parameter in which an overlay three-dimensionally increases away from a center to opposing sides of the first PR pattern in a first direction perpendicular to a scan direction of the EUV exposure process;
determining whether the first overlay is in an allowable range;
etching the wafer using the first PR pattern, when it is determined that the first overlay is in the allowable range;
performing a subsequent semiconductor process on the wafer, when it is determined that the first overlay is in the allowable range;
calculating deformation data of the reticle based on the first overlay, when it is determined that the first overlay is out of the allowable range;
applying a voltage, based on the deformation data, to a clamp electrode of a reticle stage on which the reticle is settled to create the reticle into a deformed reticle; and
performing an EUV exposure process using the deformed reticle to form a second PR pattern on the wafer.

17. The method of claim 16, wherein the clamp electrode comprises a plurality of split electrodes arranged in a two-dimensional array structure,
wherein voltages are applied to the split electrodes, respectively, to create the deformed reticle, and
wherein the deformed reticle is formed in a shape of a parabola having a center as an upper portion and opposing edges in the first direction as respective lower portions.

18. The method of claim 16, wherein the EUV exposure process using the deformed reticle comprises applying a tilt to the deformed reticle in a rotational direction about the first direction.

19. The method of claim 16, wherein forming the first PR pattern comprises:
applying PR on the wafer;
performing EUV exposure on the PR; and
developing the PR.

20. The method of claim 16, wherein, before performing the EUV exposure process using the deformed reticle, the first PR pattern on the wafer is removed and a new PR is applied on the wafer.
